(19) United States
(12) Patent Application Publication
(10) Pub. No.: US 2025/0211010 A1
(43) Pub. Date: Jun. 26, 2025

(54) DISCHARGING CIRCUIT OF ENERGY STORAGE MODULE, BACKUP POWER CAPACITY DETERMINATION METHOD FOR ENERGY STORAGE MODULE, AND RELATED ASSEMBLY

(71) Applicant: SUZHOU METABRAIN INTELLIGENT TECHNOLOGY CO., LTD., Suzhou, Jiangsu (CN)

(72) Inventors: Yaoyu HUA, Suzhou, Jiangsu (CN); Ji ZHONG, Suzhou, Jiangsu (CN)

(21) Appl. No.: 18/846,230

(22) PCT Filed: Feb. 24, 2023
(86) PCT No.: PCT/CN2023/078097

§ 371 Date: Sep. 11, 2024

(30) Foreign Application Priority Data
Sep. 8, 2022 (CN) 202211092541.2

(51) Int. Cl. H02J 7/00; G01R 31/367; G01R 31/389

(52) U.S. Cl. CPC H02J 7/0063; G01R 31/367; G01R 31/389; H02J 7/00047; H02J 7/0048; H02J 7/00714; H02J 7/007182; H02J 2207/50

(57) ABSTRACT

The present disclosure discloses a discharging circuit of an energy storage module, a backup power capacity determination method for an energy storage module, and a related assembly. The discharging circuit includes a constant-current source discharging circuit and a processor; the processor generates a target discharging current corresponding to a target type of an energy storage module; and when the energy storage module discharges by means of the constant-current source discharging circuit, the discharging current of the energy storage module is the target discharging current. Therefore, according to the present disclosure, different target discharging currents may be set for different types of energy storage module, and the energy storage module discharges at a constant target discharging current in a discharging process by means of the constant-current source discharging circuit.

### CROSS-REFERENCE TO RELATED APPLICATION

The present disclosure claims the priority of the Chinese patent application filed on Sep. 8, 2022 before the CNIPA, China National Intellectual Property Administration with the application number of 202211092541.2 and the title of “DISCHARGING CIRCUIT OF ENERGY STORAGE MODULE, BACKUP POWER CAPACITY DETERMINATION METHOD FOR ENERGY STORAGE MODULE, AND RELATED ASSEMBLY”, which is incorporated herein in its entirety by reference.

### FIELD

The present disclosure relates to the technical field of server storage, in particular to a discharging circuit of an energy storage module, a backup power capacity determination method for the energy storage module, and a related assembly.

### BACKGROUND

At present, a backup power capacity of a backup power supply (usually a battery, an supercapacitor or other energy storage module that may achieve an energy storage function) in a storage server is evaluated in the following way: a switch and a resistor are connected to an output end of the backup power supply; the switch is controlled to be turned on when the backup power capacity of the backup power supply needs to be evaluated, so as to realize the discharge of the backup power supply; and a capacity of the backup power supply and the backup power capacity of the backup power supply are calculated based on discharging duration and a discharging current.

However, the discharging current of the backup power supply during the discharging process is not constant, and discharging currents allowed by different types of backup power supplies are different, so there is a deviation in the capacity and backup power capacity of the backup power supply calculated by the discharging mode in the prior art. When this backup power supply is applied to the storage server, the storage server has a hidden danger of data loss.

### SUMMARY

The present disclosure provides a discharging circuit of an energy storage module, a backup power capacity determination method for the energy storage module, and a related assembly. Different target discharging currents may be set for different types of energy storage modules. In addition, the energy storage module discharges at a constant target discharging current in a discharging process by means of a constant-current source discharging circuit, so that the accuracy and reliability of calculating the backup power capacity of the energy storage module may be improved when the backup power capacity of the energy storage module is evaluated based on the target discharging current of the energy storage module. Further, when the energy storage module is applied to a storage server, the risk of data loss from the storage server may be reduced.

In order to solve the above technical problems, the present disclosure provides a discharging circuit of an energy storage module. The discharging circuit includes:
a constant-current source discharging circuit, connected to an output end of the energy storage module; and
a control module, connected to a control end of the constant-current source discharging circuit and configured to generate a control signal corresponding to a target type of the energy storage module so as to control the constant-current source discharging circuit, such that when the energy storage module discharges by means of the constant-current source discharging circuit, a discharging current of the energy storage module is a target discharging current.

In some embodiments, the constant-current source discharging circuit includes a thyristor, a first resistor, a first controllable switch and a second controllable switch; and
an anode of the thyristor is grounded, and a cathode of the thyristor is connected to an output end of a voltage output module and a control end of the first controllable switch; a first end of the first controllable switch is connected to the energy storage module, and a second end of the first controllable switch is connected to a reference electrode of the thyristor and one end of the first resistor, respectively; the other end of the first resistor is connected to a first end of the second controllable switch; a second end of the second controllable switch is grounded; and a control end of the second controllable switch as a control end of the constant-current source discharging circuit is connected to an output end of a processor.

In some embodiments, the discharging circuit further includes:
a second resistor, arranged between the control end and a ground end of the second controllable switch.

In some embodiments, the voltage output module further includes a third resistor and a fourth resistor; and
a first end of the third resistor is grounded, a second end of the third resistor is connected to a first end of the fourth resistor and serves as the output end of the voltage output module, and a second end of the fourth resistor is connected to a power supply.

In order to solve the above technical problems, the present disclosure further provides a backup power capacity determination method for an energy storage module, which is applied to a control module in the discharging circuit of the energy storage module as described above, an output end of the control module is connected to the control end of the constant-current source discharging circuit, and an input end of the constant-current source discharging circuit is connected to the output end of the energy storage module. The method includes:
acquiring the target type of the energy storage module in a preset scenario;
determining the target discharging current corresponding to the target type according to the target type; and
generating the control signal according to the target discharging current so as to control the constant-current source discharging circuit, such that when the energy storage module discharges by means of the constant-current source discharging circuit, the discharging current of the energy storage module is the target discharging current, and the backup power capacity of the energy storage module is calculated according to the target discharging current.

In some embodiments, after acquiring the target type of the energy storage module, the method further includes:
determining an initial voltage and a cut-off voltage of the energy storage module in a discharging process according to the target type, the initial voltage being greater than the cut-off voltage; and
the generating the control signal according to the target discharging current and controlling the energy storage module to discharge based on the control signal by means of the constant-current source discharging circuit with the target discharging current as the discharging current include:
in response to an output voltage of the energy storage module being the initial voltage, generating the control signal according to the target discharging current, and controlling the energy storage module to discharge based on the control signal by means of the constant-current source discharging circuit with the target discharging current as the discharging current; and
in response to the output voltage of the energy storage module being the cut-off voltage, controlling the energy storage module to stop discharging.

In some embodiments, after determining the initial voltage and the cut-off voltage of the energy storage module in the discharging process according to the target type, the method further includes:
comparing the output voltage of the energy storage module with the initial voltage;
in response to the output voltage being greater than the initial voltage, controlling the energy storage module to discharge until the output voltage is reduced to the initial voltage; and
in response to the output voltage being less than the initial voltage, charging the energy storage module until the output voltage is increased to the initial voltage.

In some embodiments, when the output voltage of the energy storage module is the cut-off voltage, after controlling the energy storage module to stop discharging, the method further includes:
acquiring a final stabilized voltage of the energy storage module after a preset duration, the final stabilized voltage being greater than the cut-off voltage and less than the initial voltage; and
evaluating the backup power capacity of the energy storage module based on the initial voltage, the cut-off voltage, the final stabilized voltage, the target discharging current and discharging duration;
where the discharging duration being t a duration taken for the output voltage of the energy storage module to reduce from the initial voltage to the cut-off voltage.

In some embodiments, the evaluating the backup power capacity of the energy storage module based on the initial voltage, the cut-off voltage, the final stabilized voltage, the target discharging current and the discharging duration includes:
calculating an electric capacity of the energy storage module based on the initial voltage, the final stabilized voltage, the target discharging current and the discharging duration;
calculating an internal resistance value of the energy storage module based on the cut-off voltage, the final stabilized voltage and the target discharging current; and
calculating the backup power capacity of the energy storage module according to the target discharging current, the discharging duration, as well as an output voltage and a state of charge SOC of the energy storage module at any moment in the discharging process.

In some embodiments, the calculating the electric capacity of the energy storage module based on the initial voltage, the final stabilized voltage, the target discharging current and the discharging duration includes:
calculating the electric capacity of the energy storage module using a first formula based on the initial voltage, the final stabilized voltage, the target discharging current and the discharging duration, the first formula being: Capacitance=(I_{d}*t_{d})/(V_{w}−V_{f}); and
the calculating the internal resistance value of the energy storage module based on the cut-off voltage, the final stabilized voltage and the target discharging current includes:
calculating the internal resistance value of the energy storage module using a second formula based on the cut-off voltage, the final stabilized voltage and the target discharging current, the second formula being: ESR=(V_{f}−Vₘᵢₙ)/I_{d}; and
calculating the backup power capacity of the energy storage module using a third formula according to the target discharging current, the discharging duration, as well as the output voltage and SOC of the energy storage module at any moment in the discharging process, the third formula being:

$$Capacity = {\int }_{0}^{{t}_{d}} ( {I}_{d} * V ) / S O C$$

where Capacitance is the electric capacity of the energy storage module; I_{d} is the target discharging current; t_{d} is the discharging duration; V_{w} is the initial voltage; V_{f} is the final stabilized voltage; ESR is the internal resistance value of the energy storage module; Vₘᵢₙ is the cut-off voltage; Capacity is the backup power capacity of the energy storage module; ∫ is an integral symbol; V is the output voltage of the energy storage module at any moment in the discharging process; and SOC is the state of charge of the energy storage module in the discharging process.

In some embodiments, after acquiring the target type of the energy storage module, the method further includes:
determining preset duration according to the target type, the preset duration being not less than a duration taken for the output voltage to recover from the cut-off voltage to the final stabilized voltage after the energy storage module stops discharging.

In some embodiments, the generating the control signal according to the target discharging current and controlling the energy storage module to discharge based on the control signal by means of the constant-current source discharging circuit with the target discharging current as the discharging current include:
sampling a current discharging current of the energy storage module;
generating the control signal based on the target discharging current and the current discharging current; and
controlling the energy storage module to discharge based on the control signal by means of the constant-current source discharging circuit, so that the discharging current of the energy storage module is stabilized at the target discharging current.

In some embodiments, after sampling the current discharging current of the energy storage module, the method further includes:
sampling a current output voltage of the energy storage module; and
the generating the control signal based on the target discharging current and the current discharging current includes:
generating the control signal through a proportion integral differential (PID) algorithm based on the current output voltage, the target discharging current and the current discharging current.

In some embodiments, before sampling the current discharging current of the energy storage module, the method further includes:
acquiring an error output voltage and an error output current of the energy storage module in response to the energy storage module not discharging;
compensating the error output voltage so that the output voltage of the energy storage module is zero; and
compensating the error output current so that the output current of the energy storage module is zero.

In some embodiments, when the energy storage module is a backup power supply in a storage server, before acquiring the target type of the energy storage module, the method further includes:
determining whether the storage server is restarted; and
in response to the storage server being restarted, determining a scenario in which the storage server is restarted as a preset scenario.

In some embodiments, when the energy storage module is a backup power supply in a storage server, before acquiring the target type of the energy storage module, the method further includes:
determining whether the energy storage module has a plugging and unplugging action; and
in response to the energy storage module having the plugging and unplugging action, determining a scenario in which the energy storage module has the plugging and unplugging action as the preset scenario.

In some embodiments, before acquiring the target type of the energy storage module, the method further includes:
acquiring an evaluation sign for a previous evaluation of the backup power capacity of the energy storage module;
determining whether a process of the previous evaluation of the backup power capacity of the energy storage module is normal according to the evaluation sign; and
in response to the process of the previous evaluation of the backup power capacity of the energy storage module being abnormal, determining a scenario in which the evaluation process is abnormal as the preset scenario.

In some embodiments, after determining whether the process of the previous evaluation of the backup power capacity of the energy storage module is normal according to the evaluation sign, the method further includes:
in response to the evaluation process being normal, acquiring evaluation time of the previous evaluation of the backup power capacity of the energy storage module;
determining whether a time interval between current time and the evaluation time exceeds a preset time interval; and
in response to the time interval exceeding the preset time interval, determining a scenario in which the time interval exceeds the preset time interval as the preset scenario.

In some embodiments, the acquiring the target type of the energy storage module includes:
acquiring a model of the energy storage module, a model of a battery cell in the energy storage module and a model of a supercapacitor in the energy storage module.

In order to solve the above technical problems, the present disclosure further provides a backup power capacity determination system for an energy storage module, which is applied to a processor in a storage server, an output end of the control module is connected to a control end of a constant-current source discharging circuit, and an input end of the constant-current source discharging circuit is connected to an output end of the energy storage module. The system includes:
a type acquisition unit, configured to acquire a target type of the energy storage module in a preset scenario;
a current determination unit, configured to determine a target discharging current corresponding to the target type according to the target type; and
a control unit, configured to generate a control signal according to the target discharging current and control the energy storage module to discharge based on the control signal by means of the constant-current source discharging circuit with the target discharging current as the discharging current, so as to calculate the backup power capacity of the energy storage module according to the target discharging current.

In order to solve the above technical problems, the present disclosure further provides a backup power capacity determination apparatus for an energy storage module. The backup power capacity determination apparatus includes:
a memory, configured to store a computer program therein; and
a processor, configured to implement steps of the backup power capacity determination method for the energy storage module while storing the computer program.

In order to solve the above technical problems, the present disclosure further provides a non-transitory computer-readable storage medium, storing a computer program therein, the computer program being executed by a processor to implement steps of the backup power capacity determination method for the energy storage module as described above.

In order to solve the above technical problems, the present disclosure further provides a storage server, including an energy storage module, a constant-current source discharging circuit and a backup power capacity determination apparatus for the energy storage module as described above, the output end of the energy storage module is connected to the input end of the constant-current source discharging current, and the control end of the constant-current source discharging circuit is connected to the backup power capacity determination apparatus for the energy storage module.

The present disclosure provides a discharging circuit of an energy storage module, a backup power capacity determination method for the energy storage module, and a related assembly, which relate to the technical field of server storage. The discharging circuit includes a constant-current source discharging circuit and a processor; the processor generates a target discharging current corresponding to a target type of an energy storage module; and when the energy storage module discharges by means of the constant-current source discharging circuit, the discharging current of the energy storage module is the target discharging current. Therefore, according to the present disclosure, different target discharging currents may be set for different types of energy storage module, and the energy storage module discharges at a constant target discharging current in a discharging process by means of the constant-current source discharging circuit, so that when the backup power capacity of the energy storage module is subsequently evaluated on the basis of the target discharging current of the energy storage module, the accuracy and reliability of calculating the backup power capacity of the energy storage module may be improved, thereby reducing the risk of data loss of a storage server when the energy storage module is applied to the storage server.

### BRIEF DESCRIPTION OF THE DRAWINGS

In order to describe the technical solutions of the embodiments of the present disclosure more clearly, the following briefly introduces the accompanying drawings required for describing the prior art and the embodiments. Apparently, the accompanying drawings in the following description show only some embodiments of the present disclosure, and a person skilled in the art may still derive other drawings from these accompanying drawings without creative efforts.

FIG. 1 is a schematic structural diagram of a discharging circuit of an energy storage module provided in the present disclosure;

FIG. 2 is a schematic flow chart of a backup power capacity determination method for an energy storage module provided in the present disclosure;

FIG. 3 is a schematic diagram of a current and a voltage in a discharging process of an energy storage module provided in the present disclosure;

FIG. 4 is a structural block diagram of a backup power capacity determination system for an energy storage module provided in the present disclosure;

FIG. 5 is a structural block diagram of a backup power capacity determination apparatus for an energy storage module provided in the present disclosure; and

FIG. 6 is a structural block diagram of a storage server provided in the present disclosure.

### DETAILED DESCRIPTION OF THE EMBODIMENTS

The present disclosure provides a discharging circuit of an energy storage module, a backup power capacity determination method for the energy storage module, and a related assembly. Different target discharging current may be set for different types of energy storage module. In addition, the energy storage module discharges at a constant target discharging current in the discharging process by means of a constant-current source discharging circuit, so that the accuracy and reliability of calculating the backup power capacity of the energy storage module may be improved when the backup power capacity of the energy storage module is evaluated subsequently based on the target discharging current of the energy storage module. Further, when the energy storage module is applied to a storage server, the risk of data loss from the storage server may be reduced.

In order to make the objectives, technical solutions and advantages of the embodiments of the present disclosure more clearly, the technical solutions in the embodiments of the present disclosure will be described clearly and completely in conjunction with the accompanying drawings in the embodiments of the present disclosure. Apparently, the described embodiments are merely some embodiments, rather than all embodiments, of the present disclosure. Based on the embodiments of the present disclosure, all other embodiments derived by a person skilled in the art without creative efforts shall fall within the protection scope of the present disclosure.

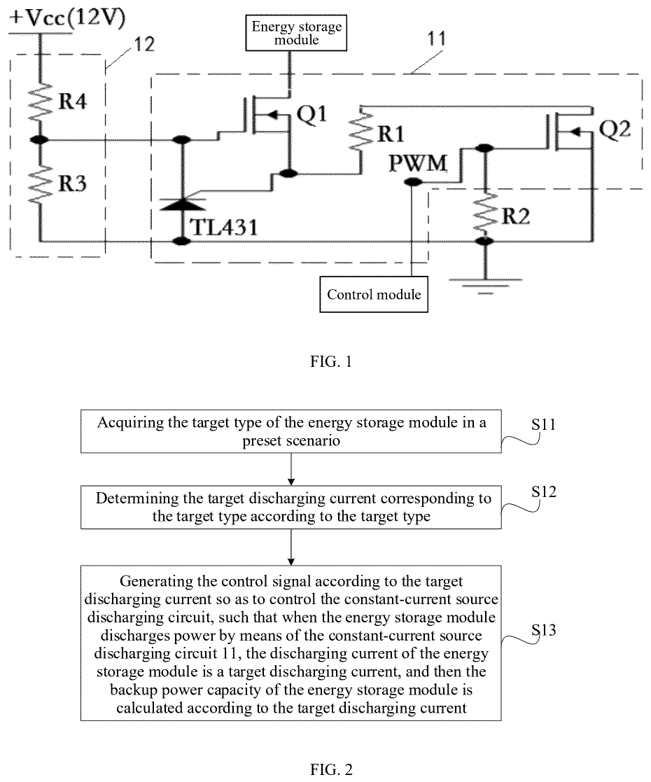

Referring to FIG. 1, FIG. 1 is a schematic structural diagram of a discharging circuit of an energy storage module provided in the present disclosure. The circuit includes:
a constant-current source discharging circuit 11, connected to an output end of the energy storage module; and
a control module, connected to a control end of the constant-current source discharging circuit 11 and configured to generate a control signal corresponding to a target type of the energy storage module so as to control the constant-current source discharging circuit 11, such that when the energy storage module discharges by means of the constant-current source discharging circuit 11, the discharging current of the energy storage module is a target discharging current.

In some embodiments, the design idea of the present disclosure is to control the discharging current of the energy storage module to remain stable in the discharging process of the energy storage module, so that calculation results are more accurate when the backup power capacity of the energy storage module is calculated based on the stable discharging current.

Therefore, the constant-current source discharging circuit 11 is arranged in the present disclosure, which is connected to the output end of the energy storage module, so that the energy storage module discharges at a constant discharging current. Further, the present disclosure further considers that optimal discharging current values corresponding to different types of energy storage modules may be different. Therefore, the control signal generated by the processor in the present disclosure when controlling the constant-current source discharging circuit 11 is determined based on the target type of the energy storage module, and then the discharging current when the energy storage module is controlled to discharge by means of the constant-current source discharging circuit 11 is a constant target discharging current.

As an embodiment, the constant-current source discharging circuit 11 includes a thyristor TL431, a first resistor R1, a first controllable switch Q1 and a second controllable switch Q2.

An anode of the thyristor TL431 is grounded, and a cathode of the thyristor TL431 is connected to an output end of the voltage output module 12 and a control end of the first controllable switch Q1; a first end of the first controllable switch Q1 is connected to the energy storage module, and a second end of the first controllable switch Q1 is connected to a reference electrode of the thyristor TL431 and one end of the first resistor R1, respectively; the other end of the first resistor R1 is connected to a first end of the second controllable switch Q2; a second end of the second controllable switch Q2 is grounded; and a control end of the second controllable switch Q2 as a control end of the constant-current source discharging circuit 11 is connected to an output end of a processor.

The present embodiment aims to provide an implementation of a constant-current source discharging circuit 11, among them, a first controllable switch Q1 and a second controllable switch Q2 may be but not limited to an N-Metal-Oxide-Semiconductor (NMOS), and the control signal may be but not limited to a Pulse Width Modulation (PWM) signal. A constant-current discharging function is achieved by means of the thyristor TL431. In some embodiments, a voltage outputted by the voltage output module 12 causes the thyristor TL431 to operate in a constant-current region, and then the discharging current when the energy storage module discharges is adjusted according to a duty cycle of the control signal (PWM) outputted by the processor to Q2, so that the discharging current is the target discharging current. In some embodiments, when Q1 and Q2 are NMOSs, if a control end of the second controllable switch Q2 is at a high level, the second controllable switch Q2 and the first controllable switch Q1 are turned on, and the energy storage module begins to discharge by means of the first controllable switch Q1, the first resistor R1 and the second controllable switch Q2.

Among them, +Vcc in FIG. 1 is a power supply of the constant-current source discharging circuit 11, it may be but not limited to 12 V.

As an embodiment, the discharging circuit 11 further includes:
a second resistor R2, arranged between a control end and a ground end of the second controllable switch Q2.

Further, the second resistor R2 is also further arranged as a pull-down resistor so as to ensure the reliability of the operation of the second controllable switch Q2.

As an embodiment, the voltage output module 12 includes a third resistor R3 and a fourth resistor R4.

A first end of the third resistor R3 is grounded, a second end of the third resistor R3 is connected to a first end of the fourth resistor R4 and serves as an output end of the voltage output module 12, and a second end of the fourth resistor R4 is connected to a power supply.

In some embodiments, the present embodiment aims to provide an implementation of a voltage output module 12. In some embodiments, R3 and R4 form a voltage-dividing circuit to provide a voltage for a cathode of the thyristor TL431, such that it operates in the constant-current region. Certainly, the implementation of the voltage output module 12 is not limited to the above examples, or may also be other implementation, which will not be limited in the present disclosure.

Referring to FIG. 2, FIG. 2 is a schematic flow chart of a backup power capacity determination method for an energy storage module provided in the present disclosure. This method is applied to a control module in the discharging circuit of the energy storage module as described above. An output end of the control module is connected to the control end of the constant-current source discharging circuit 11, and an input end of the constant-current source discharging circuit 11 is connected to the output end of the energy storage module. The method includes:
S11: acquiring the target type of the energy storage module in a preset scenario.

In some embodiments, when it is necessary to determine the backup power capacity of the energy storage module, the step of evaluating the backup power capacity in the present disclosure is initiated. Considering that the types of different energy storage modules are different due to their own structural reasons, the discharging currents that need to be set for different types of energy storage modules are also different.

Therefore, in the present disclosure, the target type of the energy storage module is first acquired, so that the target discharging current corresponding to the energy storage module is determined according to the target type.

The energy storage module may be but not limited to a rechargeable battery or supercapacitor, etc., which will not be particularly limited herein in the present disclosure.

As an embodiment, the acquiring the target type of the energy storage module includes:
acquiring a model of the energy storage module, a model of a battery cell in the energy storage module and a model of a supercapacitor in the energy storage module.

Considering that even for the same target type, the corresponding discharging currents may be different depending on different manufacturers and/or sources. Therefore, when the target type of the energy storage module is acquired in the present disclosure, not only a model of the energy storage module, but also a model of a battery cell and a model of the supercapacitor in the energy storage module are acquired, so as to comprehensively determine the target discharging current corresponding to the current energy storage module.

As an embodiment, when the energy storage module is a backup power supply in the storage server, before acquiring the target type of the energy storage module, the method further includes:
determining whether the storage server is restarted; and
in response to the storage server being restarted, determining a scenario in which the storage server is restarted as a preset scenario.

In some embodiments, the present embodiment aims to provide an implementation of the preset scenario, which may be, but not limited to, determining a scenario in which the storage server is restarted as the preset scenario, and the backup power capacity of the energy storage module is evaluated and determined at this time.

As an embodiment, when the energy storage module is a backup power supply in the storage server, before acquiring the target type of the energy storage module, the method further includes:
determining whether the energy storage module has a plugging and unplugging action; and
in response to the energy storage module having the plugging and unplugging action, determining a scenario in which the energy storage module has the plugging and unplugging action as the preset scenario.

In some embodiments, the present embodiment aims to provide another implementation of the preset scenario, which may be, but not limited to, determining a scenario in which the energy storage module has the plugging and unplugging action as the preset scenario when the energy storage module has the plugging and unplugging action. That is, in response to the plugging and unplugging action of the energy storage module being detected, the backup power capacity of the energy storage module begins to be evaluated.

As an embodiment, before acquiring the target type of the energy storage module, the method further includes:
acquiring an evaluation sign for the previous evaluation of the backup power capacity of the energy storage module;
determining whether the process of the previous evaluation of the backup power capacity of the energy storage module is normal according to the evaluation sign; and
in response to the process of the previous evaluation of the backup power capacity of the energy storage module being abnormal, determining a scenario in which the evaluation process is abnormal as the preset scenario.

The present embodiment aims to provide an implementation of another preset scenario. In some embodiments, each time the backup power capacity of the energy storage module is evaluated, the backup power capacity may be evaluated every other preset duration. The preset duration may be 3 months. After the evaluation is completed, the time of evaluating the backup power capacity may be recorded, and the corresponding evaluation sign may be updated at this time. In some embodiments, when the evaluation is completed, this evaluation sign indicates that the evaluation process is normal and has been completed. When the evaluation process is abnormal, this evaluation sign is an evaluation abnormality sign.

Therefore, the evaluation sign of the previous evaluation may be identified in the present disclosure to determine whether the process of the previous evaluation is normal. When the evaluation process is abnormal, the previous evaluation is not completed, and this scenario is also determined to be the preset scenario at this time.

As an embodiment, after determining whether the process of the previous evaluation of the backup power capacity of the energy storage module is normal according to the evaluation sign, the method further includes:
in response to the evaluation process being normal, acquiring evaluation time of the previous evaluation of the backup power capacity of the energy storage module;
determining whether a time interval between the current time and the evaluation time exceeds a preset time interval; and
in response to the time interval exceeding the preset time interval, determining a scenario in which the time interval exceeds the preset time interval as the preset scenario.

When the process of the previous evaluation is determined to be normal based on the evaluation sign of the previous evaluation, the evaluation time of the previous evaluation is acquired. When a time interval between the evaluation time and the current time exceeds the preset time interval (for example, the time interval exceeds 3 months), this scenario is determined as the preset scenario.

Further, in the event of receiving an evaluation instruction sent by a user or staff, the backup power capacity of the energy storage module begins to be evaluated according to the evaluation instruction. That is, when the evaluation instruction is detected, a scenario in which the evaluation instruction is received is determined as the preset scenario.

Certainly, the method of determining the preset scenario is not limited to the above examples, but may also be other implementations, which will not be limited herein in the present disclosure.

S12: determining the target discharging current corresponding to the target type according to the target type.

In some embodiments, after the target type of the energy storage module has been determined above, the target discharging current corresponding to the target type may be determined according to a corresponding relationship between the preset type and the discharging current.

S13: generating the control signal according to the target discharging current so as to control the constant-current source discharging circuit 11, such that when the energy storage module discharges by means of the constant-current source discharging circuit 11, the discharging current of the energy storage module is the target discharging current, and the backup power capacity of the energy storage module is calculated according to the target discharging current.

After the target discharging current of the energy storage module is determined, the control signal is generated to control the constant-current source discharging circuit 11, so that a current discharged by the energy storage module by means of the constant-current source discharging circuit 11 is always the target discharging current.

Through the method in the present disclosure, the energy storage module may discharge at the target discharging current corresponding to the energy storage module, and the discharging current remains stable in the discharging process, so that the calculation result is more accurate when the backup power capacity is calculated subsequently based on the current in the discharging process.

As an embodiment, the generating the control signal according to the target discharging current and controlling the energy storage module to discharge based on the control signal by means of the constant-current source discharging circuit 11 with the target discharging current as the discharging current include:
sampling a current discharging current of the energy storage module;
generating the control signal based on the target discharging current and the current discharging current; and
controlling the energy storage module to discharge based on the control signal by means of the constant-current source discharging circuit 11, so that the discharging current of the energy storage module is stabilized at the target discharging current.

In the discharging process, the current discharging current of the energy storage module is also sampled, and the discharging current of the energy storage module is controlled to be stabilized at the target discharging current based on the target discharging current and the current discharging current.

As an embodiment, after sampling the current discharging current of the energy storage module, the method further includes:
sampling a current output voltage of the energy storage module; and
the generating the control signal based on the target discharging current and the current discharging current includes:
generating the control signal using a proportion integral differential (PID) algorithm based on the current output voltage, the target discharging current, and the current discharging current.

In some embodiments, it may be but not limited to a difference between the target discharging current and the current discharging current. Through the PID algorithm, a duty cycle of PWM may be adjusted through double-loop PID control (a current loop is an inner loop, and a voltage loop is an outer loop), such that the discharging current of the energy storage module may be stabilized at the target discharging current.

As an embodiment, before sampling the current discharging current of the energy storage module, the method further includes:
acquiring an error output voltage and an error output current of the energy storage module in response to the energy storage module not discharging;
compensating the error output voltage so that the output voltage of the energy storage module is zero; and
compensating the error output current so that the output current of the energy storage module is zero.

Further, considering that the current discharging current of the energy storage module is sampled by using a sampling circuit, a sampling value outputted by the sampling circuit may be inaccurate (e.g., in the presence of phenomena such as temperature drift) due to the influences of a temperature and other external factors. Therefore, the error output voltage and the error output current of the sampling circuit caused by external factors should be compensated before the current discharging current is sampled by the sampling circuit, so that an output value of the sampling circuit that is not sampled after compensation is stabilized at zero, which in turn improves the reliability of the current discharging current and the current discharging voltage outputted by the sampling circuit.

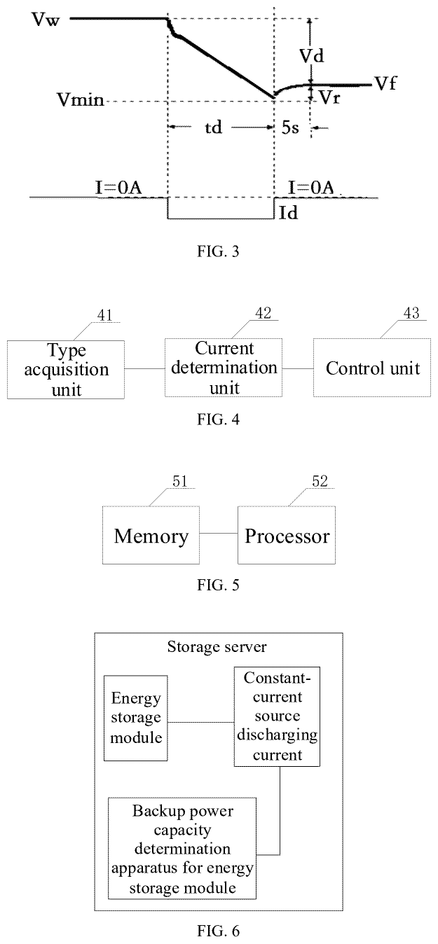

Referring to FIG. 3, FIG. 3 is a schematic diagram of a current and a voltage in a discharging process of an energy storage module provided in the present disclosure. As an embodiment, after acquiring the target type of the energy storage module, the method further includes:
determining an initial voltage and a cut-off voltage of the energy storage module in the discharging process according to the target type, the initial voltage being greater than the cut-off voltage; and
the generating the control signal according to the target discharging current and controlling the energy storage module to discharge based on the control signal by means of the constant-current source discharging circuit 11 with the target discharging current as the discharging current include:
in response to an output voltage of the energy storage module being the initial voltage, generating a control signal according to the target discharging current, and controlling the energy storage module to discharge based on the control signal by means of the constant-current source discharging circuit 11 with the target discharging current as the discharging current; and
in response to the output voltage of the energy storage module being the cut-off voltage, controlling the energy storage module to stop discharging.

In some embodiments, in order to ensure that the storage server evaluates a backup power capacity value of the energy storage module and meet the backup power demand of the storage server, the backup power capacity of the energy storage module needs to be evaluated regularly by means of shallow discharging from a constant-current source.

In some embodiments, in the event of discharging, the initial voltage and the cut-off voltage of the corresponding energy storage module in the discharging process are also different according to the different types of energy storage modules. Therefore, in the present disclosure, the corresponding initial voltage and cut-off voltage in the discharging process are determined according to the target type of the energy storage module, and then the energy storage module is controlled to start discharging from the initial voltage (discharging at the target discharging current) and stop discharging until the output voltage of the energy storage module is the cut-off voltage.

As one embodiment, after determining the initial voltage and the cut-off voltage of the energy storage module in the discharging process according to the target type, the method further includes:
comparing the output voltage of the energy storage module with the initial voltage;
in response to the output voltage being greater than the initial voltage, controlling the energy storage module to discharge until the output voltage is reduced to the initial voltage; and
in response to the output voltage being less than the initial voltage, charging the energy storage module until the output voltage is increased to the initial voltage.

In some embodiments, considering that there may be a difference between the output voltage of the energy storage module and the acquired initial voltage, in order to ensure the accurate calculation in the discharging process of the energy storage module, when the output voltage of the energy storage module is not the initial voltage in the present disclosure, the energy storage module is charged or discharged till reaching the initial voltage, and then the energy storage module is controlled to start discharging from the initial voltage until reaching the cut-off voltage. In some embodiments, in response to the output voltage being greater than the initial voltage, the energy storage module is controlled to discharge until the output voltage is reduced to the initial voltage; and in response to the output voltage being less than the initial voltage, the energy storage module is charged till the output voltage is increased to the cut-off voltage.

As shown in FIG. 3, the initial voltage is V_{w}; the cut-off voltage is Vₘᵢₙ; V_{f} is the final stabilized voltage after the discharge is stopped; and Vᵣ is a difference between the final stabilized voltage and the cut-off voltage. t_{d} is the discharging duration. The smaller the Vᵣ, the better the performance of the energy storage module (the lower the internal resistance), and vice versa, the worse the performance. When the energy storage module does not discharge, the current is 0; and in the discharging process, the current is constant (I_{d}, which is also the target discharging current).

As an embodiment, in response to the output voltage of the energy storage module being the cut-off voltage, after the energy storage module is controlled to stop discharging, the method further includes:
acquiring a final stabilized voltage of the energy storage module after a preset duration, the final stabilized voltage being greater than the cut-off voltage and less than the initial voltage;
evaluating the backup power capacity of the energy storage module based on the initial voltage, the cut-off voltage, the final stabilized voltage, the target discharging current and discharging duration;
where the discharging duration being a duration taken for the output voltage of the energy storage module to reduce from the initial voltage to the cut-off voltage.

As shown in FIG. 3, Vf is the final stabilized voltage after the energy storage module stops discharging, and the output voltage of the energy storage module will rise after a period of time and stabilize after a certain period of time, and the final stabilized voltage is the voltage that remains stable after rise. The way to acquire the final stabilized voltage may include: collecting an output voltage once every other a preset duration; and in response to the output voltages collected for two or three adjacent times are the same, determining this voltage as the final stabilized voltage.

As an embodiment, after acquiring the target type of the energy storage module, the method further includes:
determining preset duration according to the target type, the preset duration being not less than a duration taken for the output voltage to recover from the cut-off voltage to the final stabilized voltage after the energy storage module stops discharging.

Further, after the energy storage module stops discharging, the duration required for the energy storage module to rise is called standby delay. The standby delays of different energy storage modules vary depending on the type of energy storage module. For example, the standby delay of a supercapacitor is about 5 seconds, and the standby delay of a lithium-ion battery is about 1800 seconds.

Therefore, the method of determining the preset duration in the present disclosure may include: determining a duration of the corresponding standby delay according to the target type of the energy storage module; and setting the preset duration to a duration not less than the standby delay.

As an embodiment, the evaluating the backup power capacity of the energy storage module based on the initial voltage, the cut-off voltage, the final stabilized voltage, the target discharging current and the discharging duration includes:
calculating an electric capacity of the energy storage module based on the initial voltage, the final stabilized voltage, the target discharging current and the discharging duration;
calculating an internal resistance value of the energy storage module based on the cut-off voltage, the final stabilized voltage and the target discharging current; and
calculating the backup power capacity of the energy storage module according to the target discharging current, the discharging duration, as well as an output voltage and a state of charge SOC of the energy storage module at any moment in the discharging process.

After the initial voltage, the final stabilized voltage, the target discharging current and the discharging duration are acquired, the backup power capacity of the energy storage module is evaluated based on these parameters. The backup power capacity is expressed in the parameters of the electric capacity, the internal resistance value and the backup power capacity value of the energy storage module. Therefore, the three parameters of the electric capacity, the internal resistance value and the backup power capacity value are calculated in the present disclosure.

The greater the internal resistance value, the worse the performance of the energy storage module and the worse the backup power capacity.

As an embodiment, the calculating the electric capacity of the energy storage module based on the initial voltage, the final stabilized voltage, the target discharging current and the discharging duration includes:
calculating the electric capacity of the energy storage module using a first formula based on the initial voltage, the final stabilized voltage, the target discharging current and the discharging duration, the first formula being: Capacitance=(I_{d}*t_{d})/(V_{w}−V_{f}); and
the calculating the internal resistance value of the energy storage module based on the cut-off voltage, the final stabilized voltage and the target discharging current includes:
calculating the internal resistance value of the energy storage module using a second formula based on the cut-off voltage, the final stabilized voltage and the target discharging current, the second formula being: ESR=(V_{f}−Vₘᵢₙ)/I_{d}; and
calculating the backup power capacity of the energy storage module using a third formula according to the target discharging current, the discharging duration, as well as an output voltage and SOC of the energy storage module at any moment in the discharging process, the third formula being:

$$Capacity = {\int }_{0}^{{t}_{d}} ( {I}_{d} * V ) / S O C$$

where Capacitance is the electric capacity of the energy storage module; I_{d} is the target discharging current; t_{d} is the discharging duration; V_{w} is the initial voltage; V_{f} is the final stabilized voltage; ESR is the internal resistance value of the energy storage module; Vₘᵢₙ is the cut-off voltage; Capacity is the backup power capacity of the energy storage module; ∫ is an integral symbol; V is the output voltage of the energy storage module at any moment in the discharging process; and SOC is the state of charge of the energy storage module in the discharging process.

In some embodiments, the way of calculating the three parameters of the electric capacity, the internal resistance value and the backup power capacity value of the energy storage module may include: calculating the electric capacity of the energy storage module using the first formula based on the initial voltage, the final stabilized voltage, the target discharging current and the discharging duration; calculating the internal resistance value of the energy storage module using the second formula based on the cut-off voltage, the final stabilized voltage and the target discharging current; and calculating the backup power capacity of the energy storage module using the third formula according to the target discharging current, the discharging duration, as well as the output voltage and SOC of the energy storage module at any moment in the discharging process. The implementation of the first formula, the second formula and the third formula is given above, which will not be repeated herein in the present disclosure.

In summary, by applying the backup power capacity determination method for the energy storage module in the present disclosure, the target type of the energy storage module is acquired in the preset scenario; the target discharging current corresponding to the target type is determined according to the target type; the control signal is generated according to the target discharging current; and the energy storage module is controlled to discharge based on the control signal by means of the constant-current source discharging circuit 11 with the target discharging current as the discharging current. Therefore, when the backup power capacity of the energy storage module is evaluated in the present disclosure, different target discharging currents may be set for different types of energy storage module, and the energy storage module discharges at a constant target discharging current in a discharging process by means of the constant-current source discharging circuit 11. Therefore, the accuracy and reliability of calculating the backup power capacity of the energy storage module may be improved, thereby reducing the risk of data loss of a storage server when the energy storage module is applied to the storage server.

In order to solve the above technical problems, the present disclosure further provides a backup power capacity determination system for an energy storage module. Referring to FIG. 4, FIG. 4 is a structural block diagram of a backup power capacity determination system for an energy storage module provided in the present disclosure. This system is applied to a processor in a storage server, an output end of the processor is connected to a control end of a constant-current source discharging circuit 11, and an input end of the constant-current source discharging circuit 11 is connected to an output end of the energy storage module. The system includes:
a type acquisition unit 41, configured to acquire a target type of the energy storage module in a preset scenario;
a current determination unit 42, configured to determine a target discharging current corresponding to the target type according to the target type; and
a control unit 43, configured to generate a control signal according to the target discharging current and control the energy storage module to discharge based on the control signal by means of the constant-current source discharging circuit 11 with the target discharging current as the discharging current, so as to calculate the backup power capacity of the energy storage module according to the target discharging current.

The introduction of the backup power capacity determination system for the energy storage module refers to the above embodiments, which will not be repeated here.

In order to solve the above technical problems, the present disclosure further provides a backup power capacity determination apparatus for an energy storage module. Referring to FIG. 5, FIG. 5 is a structural block diagram of a backup power capacity determination apparatus for an energy storage module provided in the present disclosure. This apparatus includes:
a memory 51, configured to store a computer program therein; and
a processor 52, configured to implement the steps of the backup power capacity determination method for the energy storage module while storing the computer program.

The introduction of the backup power capacity determination apparatus for the energy storage module refers to the above embodiments, which will not be repeated here.

In order to solve the above technical problems, the present disclosure further provides a non-transitory computer-readable storage medium, having stored a computer program therein, the computer program being executed by a processor to implement the steps of the backup power capacity determination method for the energy storage module as described above. The introduction of the non-transitory computer-readable storage medium refers to the above embodiments, which will not be repeated here.

In order to solve the above technical problems, the present disclosure further provides a storage server. Referring to FIG. 6, FIG. 6 is a structural block diagram of a storage server provided in the present disclosure. This storage server includes an energy storage module, a constant-current source discharging circuit 11 and a backup power capacity determination apparatus for the energy storage module as described above, an output end of the energy storage module is connected to an input end of the constant-current source discharging current 11, and a control end of the current-current source discharging circuit 11 is connected to the backup power capacity determination apparatus for the energy storage module. The introduction of the storage server refers to the above embodiments, which will not be repeated here.

It should be noted that, as used in the present description, relation terms such as “first” and “second” are used merely to distinguish a subject or an operation from another subject or another operation, and not to require or imply any substantial relation or sequence between these subjects or operations. Moreover, terms “include”, “contain” or any variation thereof are intended to cover a nonexclusive containing, such that a process, a method, an item or a device containing a series of elements not only includes these elements, but also includes other elements that are not set forth specifically, or also includes an inherent element of such a process, method, item or device. Without further limitation, an element defined by a phrase “include a . . . ” does not mean that other same elements are excluded from the process, method, item or device including the element.

The foregoing description of the disclosed embodiments enables those skilled in the art to realize or use the present disclosure. A variety of modifications of these embodiments will be obvious to those skilled in the art, and the general principles defined herein may be implemented in other embodiments without departing from the spirit or scope of the present disclosure. Accordingly, the present disclosure will not be limited to these embodiments shown herein, but will conform to the widest range consistent with the principles and novel features disclosed herein.

1. A discharging circuit of an energy storage module, comprising:
a constant-current source discharging circuit, connected to an output end of the energy storage module; and
a control module, connected to a control end of the constant-current source discharging circuit and configured to generate a control signal corresponding to a target type of the energy storage module so as to control the constant-current source discharging circuit, such that when the energy storage module discharges by means of the constant-current source discharging circuit, a discharging current of the energy storage module is a target discharging current.

2. The discharging circuit of the energy storage module according to claim 1, wherein the constant-current source discharging circuit comprises a thyristor, a first resistor, a first controllable switch and a second controllable switch; and
an anode of the thyristor is grounded, and a cathode of the thyristor is connected to an output end of a voltage output module and a control end of the first controllable switch; a first end of the first controllable switch is connected to the energy storage module, and a second end of the first controllable switch is connected to a reference electrode of the thyristor and one end of the first resistor, respectively; the other end of the first resistor is connected to a first end of the second controllable switch; a second end of the second controllable switch is grounded; and a control end of the second controllable switch as a control end of the constant-current source discharging circuit is connected to an output end of the control module.

3. The discharging circuit of the energy storage module according to claim 2, further comprising:
a second resistor, arranged between the control end and a ground end of the second controllable switch.

4. The discharging circuit of the energy storage module according to claim 2, wherein the voltage output module comprises a third resistor and a fourth resistor; and
a first end of the third resistor is grounded, a second end of the third resistor is connected to a first end of the fourth resistor and serves as the output end of the voltage output module, and a second end of the fourth resistor is connected to a power supply.

5. A backup power capacity determination method for an energy storage module, applied to a control module in a discharging circuit of an energy storage module, wherein the discharging circuit comprises a constant-current source discharging circuit and the control module, an output end of the control module is connected to a control end of the constant-current source discharging circuit, and an input end of the constant-current source discharging circuit is connected to an output end of the energy storage module; and the method comprises:
acquiring the target type of the energy storage module in a preset scenario;
determining the target discharging current corresponding to the target type according to the target type; and
generating the control signal according to the target discharging current so as to control the constant-current source discharging circuit, such that when the energy storage module discharges by means of the constant-current source discharging circuit, the discharging current of the energy storage module is the target discharging current, and the backup power capacity of the energy storage module is calculated according to the target discharging current.

6. The backup power capacity determination method for the energy storage module according to claim 5, wherein after acquiring the target type of the energy storage module, the method further comprises:
determining an initial voltage and a cut-off voltage of the energy storage module in a discharging process according to the target type, the initial voltage being greater than the cut-off voltage; and
the generating the control signal according to the target discharging current so as to control the constant-current source discharging circuit, such that when the energy storage module discharges by means of the constant-current source discharging circuit, the discharging current of the energy storage module is the target discharging current comprising:
in response to an output voltage of the energy storage module being the initial voltage, generating the control signal according to the target discharging current, and controlling the energy storage module to discharge based on the control signal by means of the constant-current source discharging circuit with the target discharging current as the discharging current; and
in response to the output voltage of the energy storage module being the cut-off voltage, controlling the energy storage module to stop discharging.

7. The backup power capacity determination method for the energy storage module according to claim 6, wherein after determining the initial voltage and the cut-off voltage of the energy storage module in the discharging process according to the target type, the method further comprises:
comparing the output voltage of the energy storage module with the initial voltage;
in response to the output voltage being greater than the initial voltage, controlling the energy storage module to discharge until the output voltage is reduced to the initial voltage; and
in response to the output voltage being less than the initial voltage, charging the energy storage module until the output voltage is increased to the initial voltage.

8. The backup power capacity determination method for the energy storage module according to claim 6, wherein when the output voltage of the energy storage module is the cut-off voltage, after controlling the energy storage module to stop discharging, the method further comprises:
acquiring a final stabilized voltage of the energy storage module after preset duration, the final stabilized voltage being greater than the cut-off voltage and less than the initial voltage; and
evaluating the backup power capacity of the energy storage module based on the initial voltage, the cut-off voltage, the final stabilized voltage, the target discharging current and a discharging duration;
wherein the discharging duration being a duration taken for the output voltage of the energy storage module to reduce from the initial voltage to the cut-off voltage.

9. The backup power capacity determination method for the energy storage module according to claim 8, wherein the evaluating the backup power capacity of the energy storage module based on the initial voltage, the cut-off voltage, the final stabilized voltage, the target discharging current and the discharging duration comprises:
calculating an electric capacity of the energy storage module based on the initial voltage, the final stabilized voltage, the target discharging current and the discharging duration;
calculating an internal resistance value of the energy storage module based on the cut-off voltage, the final stabilized voltage and the target discharging current; and
calculating the backup power capacity of the energy storage module according to the target discharging current, the discharging duration, as well as an output voltage and a state of charge SOC of the energy storage module at any moment in the discharging process.

10. The backup power capacity determination method for the energy storage module according to claim 9, wherein the calculating the electric capacity of the energy storage module based on the initial voltage, the final stabilized voltage, the target discharging current and the discharging duration comprises:
calculating the electric capacity of the energy storage module using a first formula based on the initial voltage, the final stabilized voltage, the target discharging current and the discharging duration, the first formula being: Capacitance=(l_{d}*t_{d})/(V_{w}−V_{f}); and
the calculating the internal resistance value of the energy storage module based on the cut-off voltage, the final stabilized voltage and the target discharging current comprises:
calculating the internal resistance value of the energy storage module using a second formula based on the cut-off voltage, the final stabilized voltage and the target discharging current, the second formula being: ESR=(V_{f}−Vₘᵢₙ)/I_{d}; and
calculating the backup power capacity of the energy storage module using a third formula according to the target discharging current, the discharging duration, as well as the output voltage and SOC of the energy storage module at any moment in the discharging process, the third formula being:
$$Capacity = {\int }_{0}^{{t}_{d}} ( {I}_{d} * V ) / S O C$$
wherein Capacitance is the electric capacity of the energy storage module; I_{d} is the target discharging current; t_{d} is the discharging duration; V_{w} is the initial voltage; V_{f} is the final stabilized voltage; ESR is the internal resistance value of the energy storage module; Vₘᵢₙ is the cut-off voltage; Capacity is the backup power capacity of the energy storage module; ∫ is an integral symbol; V is the output voltage of the energy storage module at any moment in the discharging process; and SOC is the state of charge of the energy storage module in the discharging process.

11. The backup power capacity determination method for the energy storage module according to claim 8, wherein after acquiring the target type of the energy storage module, the method further comprises:
determining the preset duration according to the target type, the preset duration being not less than a duration taken for the output voltage to recover from the cut-off voltage to the final stabilized voltage after the energy storage module stops discharging.

12. The backup power capacity determination method for the energy storage module according to claim 8, wherein the generating the control signal according to the target discharging current so as to control the constant-current source discharging circuit, such that when the energy storage module discharges by means of the constant-current source discharging circuit comprises:
sampling a current discharging current of the energy storage module;
generating the control signal based on the target discharging current and the current discharging current; and
controlling the energy storage module to discharge based on the control signal by means of the constant-current source discharging circuit, so that the discharging current of the energy storage module is stabilized at the target discharging current.

13. The backup power capacity determination method for the energy storage module according to claim 12, wherein after sampling the current discharging current of the energy storage module, the method further comprises:
sampling the current output voltage of the energy storage module; and
the generating the control signal based on the target discharging current and the current discharging current comprises:
generating the control signal through a proportion integral differential (PID) algorithm based on the current output voltage, the target discharging current and the current discharging current.

14. The backup power capacity determination method for the energy storage module according to claim 13, wherein before sampling the current discharging current of the energy storage module, the method further comprises:
acquiring an error output voltage and an error output current of the energy storage module in response to the energy storage module not discharging;
compensating the error output voltage, so that the output voltage of the energy storage module is zero; and
compensating the error output current, so that the output current of the energy storage module is zero.

15. The backup power capacity determination method for the energy storage module according to claim 5, wherein when the energy storage module is a backup power supply in a storage server, before acquiring the target type of the energy storage module, the method further comprises:
determining whether the storage server is restarted; and
in response to the storage server being restarted, determining a scenario in which the storage server is restarted as the preset scenario.

16. The backup power capacity determination method for the energy storage module according to claim 5, wherein when the energy storage module is a backup power supply in a storage server, before acquiring the target type of the energy storage module, the method further comprises:
determining whether the energy storage module has a plugging and unplugging action; and
in response to the energy storage module having the plugging and unplugging action, determining a scenario in which the energy storage module has the plugging and unplugging action as the preset scenario.

17. The backup power capacity determination method for the energy storage module according to claim 5, wherein before acquiring the target type of the energy storage module, the method further comprises:
acquiring an evaluation sign for a pervious evaluation of the backup power capacity of the energy storage module;
determining whether a process of the previous evaluation of the backup power capacity of the energy storage module is normal according to the evaluation sign; and
in response to the process of the previous evaluation of the backup power capacity of the energy storage module is abnormal, determining a scenario in which the evaluation process is abnormal as the preset scenario.

18. The backup power capacity determination method for the energy storage module according to claim 17, wherein after determining whether the process of the previous evaluation of the backup power capacity of the energy storage module is normal according to the evaluation sign, the method further comprises:
in response to the evaluation process being normal, acquiring evaluation time of the previous evaluation of the backup power capacity of the energy storage module;
determining whether a time interval between current time and the evaluation time exceeds a preset time interval; and
in response to the time interval exceeding the preset time interval, determining a scenario in which the time interval exceeds the preset time interval as the preset scenario.

19. The backup power capacity determination method for the energy storage module according to claim 5, wherein the acquiring the target type of the energy storage module comprises:
acquiring a model of the energy storage module, a model of a battery cell in the energy storage module and a model of a supercapacitor in the energy storage module.

20-22. (canceled)

23. A storage server, comprising an energy storage module, a constant-current source discharging circuit and a backup power capacity determination apparatus for the energy storage module, wherein the output end of the energy storage module is connected to the input end of the constant-current source discharging current, and the control end of the constant-current source discharging circuit is connected to the backup power capacity determination apparatus for the energy storage module-; and the backup power capacity determination apparatus comprises:
a memory, configured to store a computer program therein; and
a processor, configured to implement operations comprising:
acquiring a target type of the energy storage module in a preset scenario;
determining a target discharging current corresponding to the target type according to the target type; and
generating a control signal according to the target discharging current so as to control the constant-current source discharging circuit, such that when the energy storage module discharges by means of the constant-current source discharging circuit, a discharging current of the energy storage module is the target discharging current, and a backup power capacity of the energy storage module is calculated according to the target discharging current.
